(19) United States
(12) Patent Application Publication
(10) Pub. No.: US 2026/0058092 A1
(43) Pub. Date: Feb. 26, 2026

(54) ION SOURCE

(71) Applicant: ph-instruments GmbH, Spittal a. d. Drau (AT)

(72) Inventors: Raffael Ferdigg, Spittal a. d. Drau (AT); Peter Hofmann, Spittal a. d. Drau (AT)

(21) Appl. No.: 19/103,286

(22) PCT Filed: Jul. 26, 2023
(86) PCT No.: PCT/EP2023/070674

§ 371 Date: Feb. 12, 2025

(30) Foreign Application Priority Data
Aug. 16, 2022 (DE) 10 2022 120 621.1

(51) Int. Cl. H01J 37/244; H01J 37/18

(52) U.S. Cl. CPC H01J 37/244; H01J 37/18

(57) ABSTRACT

The invention relates, inter alia, to an ion source (10) for generating ions (16) or ion beams (16a), comprising an ion generation chamber (11) in which the ions (16) are generated. In order to monitor the ion source (10) and in particular to ensure its safety, it is realised according to the invention that the ion source (10) comprises a pressure measuring device (30) associated with the ion generation chamber (11), wherein the pressure measuring device (30) comprises a first pressure measuring device (31), which is designed in particular in the form of a gas friction pressure gauge, or which comprises in particular a gas friction pressure gauge. Furthermore, the invention also relates to a method for handling such an ion source (10).

### REFERENCE TO PENDING PRIOR PATENT APPLICATIONS

This patent application is a 371 national stage entry of pending prior International (PCT) Patent Application No. PCT/EP2023/070674, filed 26 Jul. 2023 by ph-instruments GmbH for ION SOURCE, which patent application, in turn, claims benefit of German Patent Application No. 10 2022 120 621.1, filed 16 Aug. 2022.

The two (2) above-identified patent applications are hereby incorporated by reference.

### FIELD OF THE INVENTION

The present invention relates firstly to an ion source. Furthermore, the invention relates to an ion generating device with an ion source, as well as to a method for handling an ion source, in particular for generating ions in an ion source.

### BACKGROUND OF THE INVENTION

An ion source, also known as an ion gun or, depending on the design, a plasmatron, is used to generate ions and, depending on the design, also to generate ion beams. Ions are often generated in an ion generation chamber. The ions and possibly a more or less directed movement of ions are first generated in the ion generation chamber. This often takes place in a vacuum. Ion sources per se are known in various ways from the state of the art and are familiar to experts, so there is no need to go into them in more detail here.

Ion sources are, in particular, components of ion generation devices, or they are components of systems in which ions are used in the processing of workpieces. Ion sources can be used in a wide variety of areas, for example in nuclear fusion, in mass spectrometers, in implantation systems, in ion microprobes, in rocket propulsion systems and the like.

DE 10 2021 129 731 A1 of the applicant discloses an ion generation device which is used in an implantation system. The implantation system comprises an ion generation device, which in turn comprises an ion source as a component. The ions are generated by means of the ion source. An ion beam is generated in a device for generating an ion beam. This device comprises a device for extracting the ions by means of an electrostatic field and/or a device for separating the ions by mass in a mass spectrometer and/or a device for accelerating the ions. Furthermore, the ion generation device comprises a device for deflecting the ion beam in the electric field, by means of which the ion beam is directed onto a workpiece to be processed. Finally, the ion generation device comprises means for implanting the ions in the workpiece to be processed. The workpiece is located in a process chamber of the implantation system, whereby the implantation process also takes place within the process chamber of the implantation system. The ion beams generated in the ion source and directed in the ion generation device impinge on the workpiece to be processed. A pressure measuring device in the form of a gas friction pressure manometer is assigned to the process chamber of the implantation system. The pressure measuring device is used to measure the pressure, in particular a vacuum, in the process chamber of the implantation system during the implantation process. The pressure measurement signal generated is used to determine a correction factor, which also takes into account ions neutralized in the process.

### SUMMARY OF THE INVENTION

It is the object of the present invention to further improve the performance of such an ion source.

According to the invention, this object is solved by the ion source with the features according to independent claim 1, which forms the first aspect of the invention, by the ion generating device with the features according to independent claim 10, which forms the second aspect of the invention, and by the method with the features according to independent claim 11, which forms the third aspect of the invention.

Further features and details of the invention can be derived from the dependent claims, from the description and from the drawings. Features and details described in connection with one of the aspects of the invention also apply in full in connection with the respective other aspects of the invention, and vice versa, so that with regard to the disclosure of one of the aspects of the invention, reference is always made in full to the disclosure of the other two aspects of the invention.

The present invention is not limited to specific areas of application for ion sources. Similarly, the invention is not limited to specific types of ion sources.

The basic idea of the present invention is that a pressure measuring device is now directly associated with the ion source. The pressure of the ion source, in particular at or in the ion source, is thus determined, preferably individually for the ion source. In this way, the performance of the ion source is further improved. This can be achieved in various ways. For example, the ion source can be specifically controlled and/or monitored using the pressure determined by the pressure measuring device. In particular, the pressure measuring device can also be used to determine and/or control and/or monitor important parameters of the ion source, in particular control parameters. Alternatively, or additionally, the pressure measuring device can also be used to monitor the safety of the ion source.

According to the present invention, at least one gas friction pressure gauge is used in particular for pressure and process monitoring in the area of the ion source. The invention is not limited to this embodiment.

Monitoring is preferably carried out independently of the area of application and the application process in which and for which the ion source is used. Monitoring takes place directly, i.e. immediately, at the ion source. This allows influence to be exerted at a very early stage if necessary.

According to the first aspect of the invention, there is provided an ion source comprising the features of independent claim 1.

The ion source is used to generate ions or ion beams. This means that the ion source is provided so that at least ions, and depending on the configuration also ion beams, are generated or can be generated. In particular, an ion source is a device with which ions are generated. Ions are electrically charged atoms. The ion source according to the invention can be used to generate both positive and negative, as well as singly and multiply charged ions of a wide variety of chemical elements. In a simple embodiment, the ion source is used to generate ions. In another embodiment, the ion source is used to generate ion beams in addition to generating the ions themselves. In this case, the ion source generates a more or less directed movement of the ions.

The ion source consists of at least one ion generation chamber in which the ions are generated. A chamber is in particular a preferably small space, which is largely or completely enclosed, in which the ions are generated. In one embodiment, the ion generation chamber comprises a chamber wall that delimits a chamber inner space. If required, one or more connections for further components, inlets and outlets can be provided in the chamber wall, as described in more detail below by reference of exemplary examples. The ion generation chamber can, for example, be designed as a cylindrical chamber, although the invention is of course not limited to this specific embodiment.

In a further embodiment, however, the ion source can also comprise further components which are located on or in the ion generation chamber and which are designed and provided to generate an ion beam, in particular a directed ion beam. These components can be of different types depending on the nature of the ion source.

Furthermore, according to the invention, the ion source comprises a pressure measuring device associated with the ion generation chamber, wherein the pressure measuring device comprises at least a first pressure measuring device. According to the invention, a pressure measuring device is thus directly associated with the ion generation chamber. This means that the pressure measuring device is provided in such a way that it co-operates with the ion generation chamber, in particular in order to be able to determine the pressure in the ion generation chamber. A pressure measuring device is in particular a device by means of which a pressure, in particular the pressure ratios, are detected, for example measured or determined. In one embodiment, the pressure measuring device is connected to the ion generation chamber, preferably in such a way that the pressure at or in the ion generation chamber is measured or can be measured with the pressure measuring device.

The pressure measuring device and the first pressure measuring device can be designed in different ways. Some embodiments on this are explained further on in the description.

In one embodiment, the pressure measuring device is designed in the form of a physical entity. An entity is to be understood as a unit. A physical entity is a physical unit. All components thus represent internal components in relation to the pressure measuring device. In particular, this means that all components are arranged or formed within a housing.

In a second embodiment, the pressure measuring device is designed partly in the form of a physical entity and partly in the form of a functional entity. A functional entity is characterised in particular by the fact that the components are spatially separated from each other and the entity results from the functional interaction of the individual components. In this case, only a subgroup of the components are internal components in the sense of the first embodiment. At least one component of the pressure measuring device is designed as an external component thereto.

In a third embodiment, the pressure measuring device is designed as a purely functional entity. This means that all components are each designed as independent, spatially separate components. However, the individual components are functionally connected to each other in a suitable manner to realise the pressure measuring device.

According to the invention, the pressure measuring device comprises a first pressure measuring device which is designed in a special way.

In principle, the invention is not limited to certain types of first pressure measuring devices. A number of embodiments are described in the course of the description. In one embodiment, the first pressure measuring device is designed as a pressure measuring device for high-precision and/or long-term stable pressure measurement. In a preferred embodiment, the first pressure measuring device is designed in the form of a gas friction pressure gauge, which is also referred to synonymously as SRG in the description, or it comprises a gas friction pressure gauge.

The pressure in the ion generation chamber, which is often an underpressure, particularly a vacuum, can be measured very accurately using a gas friction pressure gauge. The pressure measurement signal generated can also be used to determine a correction factor.

The gas friction pressure gauge (SRG) is non-ionizing, is less dependent on gas types compared to many other measuring devices, such as ionization gauges or Piranis, is less sensitive to coatings and, above all, is very stable over the long term. This is particularly due to the fact that only the decrease in the rotational frequency of a sphere rotating contactless in a vacuum is determined. This is a mathematical method, without any electrical and/or mechanically loaded components in the measuring range.

The gas friction pressure gauge is characterised by high precision and absolute accuracy and/or long-term stability. Furthermore, it should not affect the vacuum, be resistant to the media used and be as insensitive to contamination as possible.

According to one embodiment, the gas friction pressure gauge comprises a rotating ball. Such a gas friction pressure gauge basically works as follows: A ball is mounted friction-free in a magnetic field. An external rotating field serves as a drive for the ball, sets the ball in rotation and causes the ball to rotate. The drive is then switched off. The ball is slowed down by the molecules in the remaining gas. Scanning coils are used to measure the decrease in rotational speed and determine the particle density of the gas. The deceleration rate can be measured directly as a measure of the density or respectively of the pressure. With this method, only the global properties of the ball are included in the measurement and are stored with a factor (calibration factor); the rest of the arrangement is not variable or subject to error. The measured pressure values provided by the gas friction pressure gauge are preferably provided in the form of electrical signals.

The gas friction pressure gauge is or enables a measuring method that is currently characterised by its high accuracy (1% of the measured value) and a wide (>6 decades) measuring range extending into the high vacuum (HV) range (>10 to 1×10⁻⁷ hPa), but in principle works in all pressure ranges. The pressure measuring device has a very simple design with a rotating ball as the sensor and operates without contact, without feedthroughs into the vacuum or mechanically stressed components. All information and interactions are transmitted into the vacuum via magnetic and electromagnetic forces. The gas friction pressure gauge therefore has no electrically or mechanically stressed components and achieves a correspondingly high long-term stability (drift<1%/year) and is also robust and corrosion-resistant, for example made of all-metal. As the measurement signal is based on the change in the rotational frequency of a spherical body and not on changes in distance or the ionization of gases, the process is far less influenced by temperature, ageing or coating effects. Due to its accuracy in a high vacuum and its long-term stability, the gas friction pressure gauge is used as a transfer standard in many calibration laboratories.

According to another embodiment, the first pressure measuring device is designed as a so-called ION gauge measuring tube. This will be explained in more detail in the further course of the description. The invention is not limited to the examples mentioned.

In principle, it is sufficient if the pressure measuring device comprises a single first pressure measuring device. According to another embodiment, the pressure measuring device comprises two or more pressure measuring devices. In one embodiment, for example, at least one pressure measuring device is designed as a first pressure measuring device in the form of a gas friction pressure gauge, or comprise a gas friction pressure gauge. However, the pressure measuring device can also comprise two or more first pressure measuring devices. Or the pressure measuring device comprises at least one first pressure measuring device and at least one further pressure measuring device, which is then preferably designed in a different way and is designated as a second pressure measuring device for differentiation. The invention is not limited to certain types of second pressure measuring devices. In the further course of the description, some examples of embodiments are described. For example, the first pressure measuring device can also be referred to as a measuring tube.

In the following, some embodiments of different pressure measuring devices are described.

If measurements are typically not taken up to atmosphere but in a vacuum, for example, at least one second pressure measuring device or a second measuring tube, for example in the form of a combined transducer, is also provided. Transducers are in particular converters or transformers that convert one form of energy into another. In one embodiment, such a combined transducer can, for example, comprise a Pirani component and a piezo component. A Pirani component is in particular a specific measuring device for measuring pressure in the rough and fine vacuum range and is generally familiar to the skilled person. If the pressure measuring device comprises only one pressure measuring device, this pressure measuring device is designed in the form of a combined transducer in one embodiment. In one embodiment, such a combined transducer can consist of a first pressure measuring device, in particular in the form of a gas friction pressure gauge, for example with a measuring range of 10-8 mbar to 10-3 mbar, and a further pressure measuring device, in particular with a Pirani component, possibly combined with a piezo component, for example with a measuring range of 10-3 mbar to 1000 mbar.

In order to cover the entire pressure range with the pressure measuring device, for example, a first pressure measuring device in the form of an ION gauge measuring tube with a measuring range of 10-8 mbar to 10-3 mbar is used according to one embodiment. An ION gauge measuring tube, which is also known as an ionization vacuum gauge, is a well-known pressure measuring device for determining pressure in the high and ultra-high vacuum range. A further, second pressure measuring device or gauge, which has a measuring range of 10-3 mbar to 1000 mbar, for example, can be provided in the form of a combined transducer. Such a combined transducer combines two measuring principles, for example “Pirani” and “piezo”, which are installed in one measuring tube. In another embodiment, this second pressure measuring device is provided as a simple transducer with only one measuring principle.

In one embodiment, a gas friction pressure gauge is used instead of the ION gauge component. In this case, the first pressure measuring device and the second pressure measuring device are provided as separate measuring tubes, for example.

According to another embodiment, the pressure measuring device is provided in the form of a single pressure measuring device. In this case, the pressure measuring device may be provided as a combined transducer covering the entire range and combining, for example, several measuring principles. For example, such a combined transducer may have an ION gauge component and, for example, a Pirani component and/or a piezo component. In one embodiment, a gas friction pressure gauge is used instead of the ION gauge component.

In one embodiment, a control device is assigned to the ion source. In particular, a control device is the totality of all components that influence the ion source. The control device can take the form of hardware components or software components, or a combination thereof. In particular, the control device comprises a processor device in which at least parts of the method according to the third aspect of the invention run. The control device preferably comprises interfaces to various components of the ion source. For example, certain values or parameters of the ion source are recorded by means of the components, transmitted to the control device, and analyzed there. Individual components of the ion source can then be controlled accordingly via the control device. This is explained in more detail below using exemplary examples, in particular also in connection with the method according to the third aspect of the invention. Depending on the embodiment, the control device is at least partially a component of the ion source. Alternatively, the control device is a component external to the ion source, which is then connected and communicates with the ion source at least temporarily, for example wirelessly or by wire, via the interfaces.

In one embodiment, the first pressure measuring device is connected to the ion generation chamber, for example via a suitable connection. In another embodiment, the first pressure measuring device is arranged in the ion generation chamber.

In one embodiment, the ion generation chamber is designed as an ion generation chamber with underpressure, in particular as a vacuum-tight ion generation chamber. For this purpose, in one embodiment, the ion generation chamber is connected to an evacuation device, for example a vacuum pump. In one embodiment, the evacuation device is connected to the control device via a suitable interface.

In one embodiment, the first pressure measuring device is aligned horizontally. This means that the first pressure measuring device has a vertical orientation with respect to the ion generation chamber. If such an arrangement is not directly possible, a corresponding angled connection, for example a corresponding angled tube or the like, can be provided between the first pressure measuring device and the ion generation chamber.

The present invention is not limited to certain types of ion sources. For example, the ionization of molecules can be achieved by impact ionization, chemical ionization, thermal ionization, or field ionization. In an electric field, for example, the ions can be accelerated after generation and focused and deflected by electric or magnetic lenses. The ion source according to the invention is not limited to certain types of ionization. The only requirement is that the ionization of the molecules takes place in an environment, in particular in a chamber, in which a pressure can be measured.

In one type of ion source, the ionization of the molecules to be ionized takes place within the ion generation chamber under underpressure or in a vacuum. In this case, the ion generation chamber is preferably connected to an evacuation device via which an underpressure/vacuum is drawn into the ion generation chamber.

In one embodiment, the ion source is designed as an ion source for electron ionization. This type of ionization is a very widely used ionization method. Electrodes from a cathode, which is in particular a so-called filament, such as a glow-filament, are accelerated by an electric field. Electrons are emitted from the surface of the cathode. These electrons are accelerated to an anode in an electric field. These electrons are sent through molecules to be ionized, for example a corresponding gas, as they move through the ion generation chamber. In particular, an acceleration voltage is applied for this purpose. When the electrons hit the molecules to be ionized, they are ionized. These molecules to be ionized, for example in the form of a gas stream, are introduced into the ion generation chamber. When molecules and electrons approach each other and interact, ionization can occur. In particular, the ion generation chamber is a vacuum-tight component. Electron ionization takes place in particular under underpressure, for example in a vacuum. The pressures prevailing in the ion generation chamber are measured by the first pressure measuring device in the form of the gas friction pressure gauge.

In one embodiment, a cathode, in particular in the form of a filament, and an anode are arranged in the ion generation chamber. In one embodiment, the cathode and/or the anode is connected to the control device via a suitable interface. It is preferable that the first pressure measuring device is provided spatially spaced from the cathode or at a spatial distance from the cathode. For example, the ion source is designed as a cold cathode source or as a hot cathode source.

In principle, however, the first pressure measuring device can be arranged at any point on or in the ion generation chamber, for example depending on where a vacuum connection is located.

In one embodiment, the ion generation chamber is connected to a supply for molecules to be ionized, in particular to a gas supply. The ion generation chamber, i.e. the chamber inner space, is supplied with molecules to be ionized, in particular in the form of a gas stream, via the supply.

In one embodiment, the supply interacts with a mass flow control device. In one embodiment, the mass flow control device is located in the feed, or it provides a transition between the supply and the ion generation chamber. In particular, the mass flow control device is a component with which the mass flow of the molecules to be ionized entering the ion generation chamber can be controlled, in particular to a setpoint value. In one embodiment, the mass flow control device is connected to the control device via an interface for this purpose. In one embodiment, the mass flow control device comprises a controller and a valve that interacts with it. The use of such a mass flow controller in conjunction with the ion source is illustrated below by way of an example. Pressure values are measured with the first pressure measuring device in the ion generation chamber and compared with setpoint values. In particular, the adjustment is carried out in the control unit. The mass flow control device is actuated accordingly as required to ensure that the setpoint values and the actual measured values match, for example by the valve opening or reducing the size of the inlet opening of the supply into the ion generation chamber accordingly. This is also described below in connection with the method according to the invention, so that at this point reference is also made in full to the corresponding explanations below.

In one embodiment, the ion source is additionally characterised by an extraction device, which serves in particular to extract the ions, for example from a plasma, and to form the beam. Accordingly, such an extraction device is provided in particular for shaping an ion beam and/or for aligning an ion beam and/or for extracting ions from the molecules to be ionized that are supplied. In one embodiment, the extraction device is part of the ion source. In this case, the ion source comprises both the ion generation chamber and an extraction device. In another embodiment, such an extraction device is associated with the ion source, in particular downstream of it. This means that the ion source works together with the extraction device, whereby the extraction device is connected downstream of the ion source. In this case, only the ions are generated in the ion source, whereby the ions are subsequently formed into an ion beam in the extraction device.

In one embodiment, the ion generation chamber comprises an outlet for the generated ions and/or for the generated ion beam.

In one embodiment, a pre-acceleration device is provided in the ion generation chamber. The pre-acceleration device pre-accelerates the generated ions in the ion generation chamber. In one embodiment, the pre-acceleration device is connected to the control device via a suitable interface.

In one embodiment, a lens device is provided in the ion generation chamber. The lens device, for example in the form of a focusing lens device, for example in the form of an electrostatic lens device, focuses the ion beam. If the lens device is designed to be variable, in one embodiment it is connected to the control device via a suitable interface.

In the embodiments described above, the pre-acceleration device and/or the focusing device are each components of the ion source. According to another embodiment, the pre-acceleration device and/or the focusing device are not components of the ion source. In this case, they are downstream or subordinate to the ion source.

The pressure measuring device, in particular the first pressure measuring device, can perform or fulfil various tasks and functions in conjunction with the ion source. Some examples of this are listed below, which can be realised either individually or in any combination. For example, the pressure measuring device, in particular the first pressure measuring device, is designed or provided for controlling and/or monitoring the ion source, in particular for determining and/or controlling and/or monitoring important parameters of the ion source, in particular control parameters, in particular for controlling and/or monitoring the mass flow control device, and/or for measuring the pressure inside the ion generation chamber, and/or for determining the cleanliness of the components inside the ion generation chamber, and/or for determining the tightness of the ion source.

For example, the pressure measuring device, in particular the first pressure measuring device, monitors the mass flow control device, i.e. it regulates the gas inlet into the ion generation chamber and thus adjusts the pressure. Or the pressure measuring device measures the pressure in the ion generation chamber itself, i.e. the quality of the vacuum. Or the pressure measuring device measures the cleanliness of the components of the ion source in the vacuum. For example, the ion source is changed approximately every fortnight due to the reaction with corrosive gases. Despite careful storage, a new ion source is coated with “dirt”, which initially diffuses into the ion generation chamber and thus causes a higher vacuum pressure. Or the pressure measuring device measures the tightness of the ion source. Maintenance and the associated ventilation can cause leaks when the system is restarted, for example if seals are not fixed properly or if components are damaged. In particular, the pressure measuring device according to the invention, in particular the first pressure measuring device, serves as a safety device in general.

According to the second aspect of the invention, there is provided an ion generating device comprising the features of independent claim 11.

The ion generating device initially comprises an ion source, with an ion generating chamber for generating the ions, and a pressure measuring device associated with the ion generating chamber, wherein the pressure measuring device comprises a first pressure measuring device, which is designed in particular in the form of a gas friction pressure gauge, or which comprises in particular a gas friction pressure gauge. In particular, the ion generating device comprises an ion source according to the first aspect of the invention. For this reason, full reference is also made at this point to the explanations relating to the first aspect of the invention in order to avoid repetition.

Furthermore, the ion generation device comprises an extraction device, which is provided for forming an ion beam and/or for directing an ion beam and/or for extracting ions from the molecules to be ionized that are supplied. In one embodiment, the extraction device is at least partially part of the ion source, or it follows the ion source. In this regard, full reference is also made to the corresponding explanations in connection with the ion source according to the invention above.

Furthermore, the ion generation device comprises a device for accelerating the ions generated in the ion source. The said acceleration device accelerates the ions to their final energy and is, in particular, a separate independent component to the pre-acceleration device described above, with which the ions generated in the ion generation chamber of the ion source are pre-accelerated. Depending on the embodiment, however, only a single acceleration device may be provided, which performs both the pre-acceleration and the final acceleration of the ions.

In addition, the ion generation device can also comprise a device for separating the ions by mass in a mass separator and/or a device for deflecting the ion beam in the electric field, by means of which the ion beam is directed onto the workpiece to be processed, in particular onto the base material of the workpiece.

All of the aforementioned components of the ion generation device can also be components of the ion source, so that such an ion source then assumes the function of an ion generation device. In another embodiment, the ion source is an independent functional and/or constructive entity in which only the ions are generated. The other features of the ion generation device are then not part of the ion source, but are associated with it.

In one embodiment, the ion source according to the invention and/or the ion generation device according to the invention is used in connection with an ion implantation system. Ion implantation is a process for introducing foreign atoms in the form of ions into a base material. In this way, the material properties of the base material can be changed. Such an implantation process basically involves the following steps: Firstly, ions are generated in an ion source, for example in an ion source according to the first aspect of the invention. The ions are then extracted by an electrostatic field. The ions are then separated by mass in a mass separator. The ions are then accelerated and deflected by means of electric fields. These steps are carried out, for example, in the ion generation device according to the invention or, as far as the extraction is concerned, possibly also in the ion source according to the invention. Finally, implantation into the base material takes place.

Ion sources according to the first aspect of the invention can, however, be used in a wide variety of areas, for example in nuclear fusion, in mass spectrometers, in implantation systems, in ion microprobes, in rocket propulsion systems and the like. The invention is not limited to specific fields of application.

According to the third aspect of the invention, a method is provided which comprises the features of independent patent claim 12. The method is for handling the ion source. That is, the method is used to determine how the ion source is used in a particular manner. In one embodiment, this utilization represents the generation of the ions or an ion beam. In one embodiment, however, the utilization also represents the monitoring and/or control of the ion source. In one embodiment, the use is a combination of the two types of use described above.

In particular, the method is used for handling an ion source according to the first aspect of the invention. At this point, in order to avoid repetition, reference is therefore also made in full to the explanations relating to the first aspect of the invention.

The ion source is provided so that ions are generated in an ionization process from molecules to be ionized in an ion generation chamber of the ion source.

The method according to the invention is characterised in that pressure values at or in the ion generation chamber are detected or determined before and/or during and/or after the ionization process via a pressure measuring device assigned to the ion generation chamber, wherein the pressure measuring device comprises a first pressure measuring device, which is designed in particular in the form of a gas friction pressure gauge, or which comprises in particular a gas friction pressure gauge. In this way, the pressure measuring device can be used to carry out pressure and process monitoring in the area of the ion source.

In one embodiment, the method is further characterised by the following steps: a) Molecules to be ionized, in particular in a gas stream, are supplied to the ion source via a supply into the ion generation chamber; b) In the ionization process, ions are generated from the molecules to be ionized in the ion generation chamber. In this way, the process also generates ions or an ion beam.

In one embodiment, the method serves to carry out pressure and process monitoring in the area of the ion source by means of the pressure measuring device before and/or during and/or after the ionization process and, based on this, to set the parameters of the ionization process in such a way that the generation of the ions is carried out on the basis of the results determined as part of the monitoring.

In one embodiment, the ion source is released or the ionization process is started when the pressure measuring device, in particular the first pressure measuring device, measures that the pressure value, in particular the vacuum pressure in the ion generation chamber, falls below a certain predetermined pressure value.

In this case, the ion source or the ionization process is only released, for example, when the gas inlet, i.e. the mass flow control device, is actuated, valves to certain vacuum pumps are actuated, vacuum shutters to the next process chamber are actuated if necessary, or similar, when the pressure measuring device, in particular the first pressure measuring device, measures that the vacuum pressure has fallen below a certain level. Otherwise, components could be damaged, the actual process could be jeopardized or harmful gases could escape from the chambers, for example in the event of a leak.

According to another embodiment, the ionization process can alternatively or additionally be started or carried out when the pressure measuring device is bypassed in the bypass. A suitable switching device, which in one embodiment is connected to the control device via a suitable interface, can then be used to switch individually, if required, whether the pressure measuring device is/will be switched on at the start of the ionization process and/or during the ionization process or is bypassed in the bypass. Such a procedure is useful, for example, if there is a risk that the pressure measuring device could fail, particularly during the ionization process.

In one embodiment, with the first pressure measuring device, in particular the first pressure measuring device, is used to monitor and/or calibrate the mass flow control device, which is provided for the supply of the molecules to be ionized. This will be illustrated by means of an example:

With a first pressure measuring device, in particular in the form of a gas friction pressure gauge due to the 100% linearity property, it is possible to calibrate the mass flow controller. In one embodiment, the standard cubic centimetres per minute (sccm) are plotted or mapped against the pressure in a graph. This is preferably done in the control device described above. The unit “sccm” is used to describe a defined flowing gas quantity, i.e. particle number or gas mass, per time period, regardless of pressure and temperature, i.e. a particle flow or mass flow. If the curve is not linear, this means that the mass flow control device is drifting, i.e. not functioning correctly.

Different processes with different gas mixtures and gas quantities are usually run on a processing system. For example, a process or a “recipe” can be composed of different gas quantities. This is illustrated by an example in which such a process or “recipe” is composed of the different gas types H2, BF3 and Ar, for example
one process: H2 (1 sccm), BF3 (2 sccm) and argon (1 sccm), and
another process: PH3 (3 sccm) and argon (1 sccm).

Occasionally, there is also an adjustment of such a process, i.e. small changes in “sccm”. This is reflected in the pressure and can be measured with the pressure measuring device, in particular with the first pressure measuring device, such as the gas friction pressure gauge. This can be used to check whether the processes and components have also adopted the changes. Many other processes with other gas mixtures and gas quantities are of course also possible.

A further advantage of the ion source according to the invention and the process according to the invention lies in the reduction of the process window. Since the solutions according to the invention, in particular the values determined with them, are reproducible and do not drift, the permitted pressure window in which the ionization process may take place can be reduced and optimized (example: process pressure 2E-5 mbar, limits with standard measuring tubes 5E-6 mbar/4E-5 mbar->limits gas friction manometer 1.6E-5 mbar/2.4E-5 mbar)). Through this optimization, the required gas quantity can be precisely determined for optimum results and ultimately the gas quantity may be reduced, resulting in cost savings.

In one embodiment, it is realised that the pressure measuring device, in particular the first pressure measuring device, controls and/or monitors the ion source, in particular determines and/or regulates and/or monitors important parameters of the ion source, in particular controls and/or monitors the mass flow control device, and/or measures the pressure within the ion generation chamber, and/or determines the cleanliness of the components within the ion generation chamber, and/or determines the tightness of the ion source.

Depending on the system and type, the measuring tubes installed as standard in connection with the generation of ions usually fail within two to eight weeks. This results in unplanned system downtimes, but at the very least requires trained personnel to repair/replace the measuring tubes. With the solutions according to the invention, these disadvantages can now be avoided.

### BRIEF DESCRIPTION OF THE DRAWINGS

The invention will now be explained in more detail with reference to the accompanying drawing. It shows

FIG. 1 a schematic view of an ion source according to the present invention; and

FIG. 2 a schematic view of a first pressure measuring device designed as a gas friction pressure gauge, which interacts with the ion source.

### DETAILED DESCRIPTION OF THE PREFERRED EMBODIMENTS

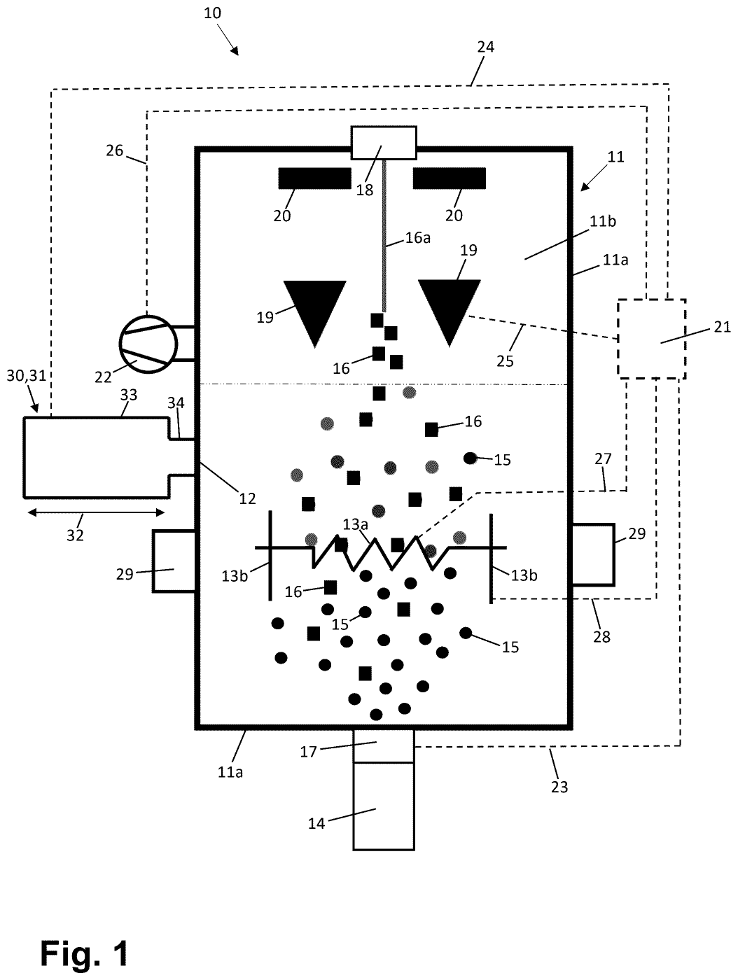

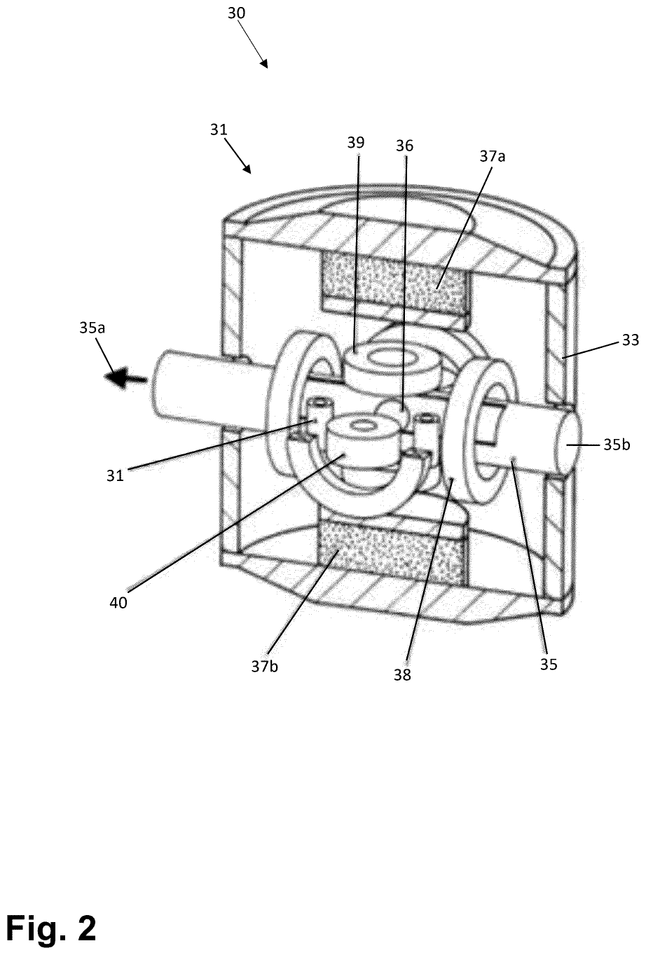

FIG. 1 shows an embodiment of an ion source 10 according to the invention. The ion source 10 comprise an ion generation chamber 11 which has a chamber wall 11a, wherein the chamber wall 11a delimits a chamber inner space 11b. The ion generation chamber 11 is connected to a connection flange 34 of a pressure measuring device 30 via a connection 12. For the sake of simplicity, this pressure measuring device 30, which will be described in greater detail later with reference to FIG. 2, only comprises a first pressure measuring device 31 in the form of a gas friction pressure gauge to illustrate the principle of the invention. The components of the first pressure measuring device 31 are located within a housing 33. The first pressure measuring device 31 is orientated vertically with respect to the ion generation chamber 11, which is shown by the arrow 32.

The ion generation chamber 11 is also connected to a supply 14 for molecules 15 to be ionized, which are fed into the ion generation chamber 11 in the form of a gas stream. The molecules 15 to be ionized are shown as small circles in FIG. 1. To control the quantity of molecules 15 to be ionized that are supplied, a mass flow control device 17 is arranged or formed in the supply 14.

To generate ions 16, which are shown as small squares in FIG. 1, a cathode 13a, which comprises a filament, and an anode 13b are arranged in the ion generation chamber 11. A magnetic field can be applied via the magnets 29 provided.

To generate an ion beam 16a, a pre-acceleration device 19 and a lens device 20 are also provided in the ion generation chamber 11. Depending on the configuration, the pre-acceleration device 19 and the lens device 20 are components of the ion source 10. Alternatively, they are independent components compared to the ion source 10, which are then connected downstream or subordinate to the ion source 10. This is shown schematically by the dot-dashed line within the ion generation chamber 11.

The generated ion beam 16a leaves the ion generation chamber 11 via an outlet 18.

In the embodiment example shown in FIG. 1, the ion source 10 is designed as an ion source for electron ionization. In this process, electrodes from the cathode 13a, which is in particular a so-called filament, such as a glow-filament, are accelerated by an electric field. Electrons are emitted from the surface of the cathode 13a. These electrons are accelerated to an anode in an electric field. These electrons are sent through molecules 15 to be ionized, for example a corresponding gas, as they move through the ion generation chamber 11. When the electrons hit the molecules 15 to be ionized, they are ionized, i.e. become ions 16.

The ion generation chamber 11 is in particular a vacuum-tight component. In particular, electron ionization takes place in a vacuum. For this purpose, the ion generation chamber 11 is connected to a vacuum pump 22. The pressures prevailing in the ion generation chamber 11 are measured by the first pressure measuring device 31 in the form of the gas friction pressure gauge.

Before and/or during and/or after the ionization process, pressure values in the ion generation chamber 11 are recorded or determined via the pressure measuring device 30 assigned to the ion generation chamber 11, which comprises at least a first pressure measuring device 31, for example in the form of the gas friction pressure gauge. In this way, the first pressure measuring device 31 can be used to carry out pressure and process monitoring in the area of the ion source 10.

For this purpose, a control device 21 is preferably assigned to the ion source 10, which is at least temporarily connected and communicates with various components of the ion source 10 via suitable interfaces. For example, the control device 21 is connected via an interface 23 to the mass flow control device 17, via an interface 24 to the first pressure measuring device 31, via an interface 25 to the pre-acceleration device 19, via an interface 26 to the vacuum pump 22, via an interface 27 to the cathode 13a, and via an interface 28 to the anode 13b. These interfaces are exemplary in nature and serve to illustrate the control device 21 and its function, so that the invention is of course not limited to the interfaces shown.

For example, the ion source 10 is only enabled or the ionization process is only started when the first pressure measuring device 31 measures that the pressure value, in particular the vacuum pressure, in the ion generation chamber 11 falls below a certain predetermined pressure value. A switch device, not shown, can also be used to switch the pressure measuring device 31 in bypass at the start of the ionization process, so that the ionization process can also be started and/or carried out without the pressure measuring device 31 if required.

For example, the first pressure measuring device 31 can be used to monitor and/or calibrate the mass flow control device 17, which is provided for the supply quantity of the molecules 15 to be ionized into the ion generation chamber 11. This will be illustrated by means of an example:

The mass flow control device 17 is connected to the control unit 21 via the interface 23. Pressure values are measured with the first pressure measuring device 31 in the ion generation chamber 11 and compared with setpoint values. The adjustment takes place in the control device 21, whereby the pressure values generated by the first pressure measuring device 31 are transmitted to the control device 21 via the interface 24. To ensure that the setpoint values and the actual measured values match, the mass flow control device 17 is actuated accordingly as required, for example by opening or reducing the size of the inlet opening of the supply 14 into the ion generation chamber 11 accordingly.

In a preferred embodiment, the first pressure measuring device 31 is designed in the form of a gas friction pressure gauge. An embodiment example of such a gas friction pressure gauge is now described with reference to FIG. 2. The individual components of the gas friction pressure gauge are located in the housing 33. One feature of the gas friction pressure gauge is formed by a vacuum tube 35 or measuring tube, which has a closed end 35b on one side and which is connected to its other end to the ion generation chamber. The direction of connection is shown here by the arrow 35a.

The gas friction pressure gauge comprises a magnet and coil system. FIG. 2 shows examples of permanent magnets 37a, 37b, as well as drive coils 38, levitation/stabilization coils 39, speed detection coils 40 and vibration damping coils 41.

A ball 36 is mounted friction-free in a magnetic field. The magnetic field is generated by the permanent magnets 37a, 37b. To maintain the height, the magnetic field of the permanent magnets 37a, 37b is superimposed with slowly varying direct current (position control) and high frequency (impedance measurement) to determine the height. The ball 36 is passively stabilized horizontally (stable equilibrium). An external rotating field (≈400 Hz) causes the ball 36 to rotate, the decrease in rotational speed is measured with a speed detection coil 40 and the particle density of the gas is measured from the friction. With this method, only the global properties of the ball 36 are included in the measurement and are stored with a factor (calibration factor); the rest of the arrangement is not variable or subject to error. The gas friction pressure gauge has a simple design (one rotating ball 36), operates contact-free and wear-free and is operated via electromagnetic forces in a vacuum. The gas friction manometer therefore has no electrically or mechanically loaded components and achieves a correspondingly high long-term stability (drift<1%/year) and is also robust and corrosion-resistant (all-metal). As the measurement signal is based on the change in the rotational frequency of a spherical body and not on a change in distance or ionization, the process is much less influenced by temperature, ageing or coating effects.

### LIST OF REFERENCE SIGNS

10 Ion source
11 Ion generation chamber
11a Chamber wall
11b Chamber inner space
12 Connection for a pressure measuring device
13a Cathode
13b Anode
14 Supply for molecules to be ionized
15 Molecules to be ionized
16 Ions
17 Mass flow control device
18 Outlet for generated ions
16a Ion beam
19 Pre-acceleration device
20 Lens device
21 Control device
22 Vacuum pump
23 Interface
24 Interface
25 Interface
26 Interface
27 Interface
28 Interface
29 Magnet
30 Pressure measuring device
31 First pressure measuring device (gas friction pressure gauge)
32 Vertical alignment
33 Housing
34 Connection flange
35 Vacuum tube (measuring tube)
35a Connection direction to the ion generation chamber
35b Closed end of the vacuum tube
36 Ball
37a Permanent magnet
37b Permanent magnet
38 Drive coil
39 Levitation/stabilization coil
40 Speed detection coil
41 Vibration damping coil

1. for generating ions (16) or ion beams (16a), comprising an ion generation chamber (11) for generating the ions (16), and a pressure measuring device (30) associated with the ion generation chamber (11), the pressure measuring device (30) comprising a first pressure measuring device (31), which is designed in particular in the form of a gas friction pressure gauge, or which comprise in particular a gas friction pressure gauge.

2. Ion source according to claim 1, characterised in that the first pressure measuring device (31) is connected to the ion generation chamber (11), or in that the first pressure measuring device (31) is arranged in the ion generation chamber (11), and/or in that the first pressure measuring device (31) is aligned vertically (32) to the ion generation chamber (11).

3. Ion source according to claim 1, characterised in that the ion generation chamber (11) is designed as an ion generation chamber with underpressure, in particular as a vacuum-tight ion generation chamber.

4. Ion source according to claim 1, characterised in that a cathode (13a), in particular in the form of a filament, and an anode (13b) are arranged in the ion generation chamber (11), and that in particular the first pressure measuring device (31) is provided at a spatial distance from the cathode (13a).

5. Ion source according to claim 1, characterised in that the ion generation chamber (11) is connected to a supply (14) for molecules (15) to be ionized, in particular to a gas supply, and in that the supply (14) interacts in particular with a mass flow control device (17).

6. Ion source according to claim 1, characterised in that the ion source (11) comprises an extraction device which is provided for forming an ion beam (16a) and/or for directing an ion beam (16a) and/or for extracting ions (16) from the molecules (15) to be ionized which are supplied, or in that such an extraction device is associated with the ion source (10).

7. Ion source according to claim 1, characterised in that the ion generation chamber (11) comprise an outlet (18) for the generated ions (16) and/or for the generated ion beam (16a), and/or in that a pre-acceleration device (19) is provided in the ion generation chamber (11), and/or in that a lens device (20) is provided in the ion generation chamber (11).

8. Ion source according to claim 1, characterised in that the pressure measuring device (30), in particular the first pressure measuring device (31), is designed or provided for controlling and/or monitoring the ion source (10), in particular for determining and/or regulating and/or monitoring important parameters of the ion source (11), in particular control parameters, in particular for controlling and/or monitoring the mass flow control device (17), and/or for measuring the pressure inside the ion generation chamber (11), and/or for determining the cleanliness of the components inside the ion generation chamber (11), and/or for determining the tightness of the ion source (10).

9. Ion source according to claim 1, characterised in that the ion source (10) is designed as an ion source for electron ionization.

10. Ion generating device, comprising
an ion source (10) with an ion generation chamber (11) for generating the ions (16), and a pressure measuring device (30) associated with the ion generation chamber (11), wherein the pressure measuring device (30) comprises a first pressure measuring device (31), which is designed in particular in the form of a gas friction pressure gauge, or which comprises in particular a gas friction pressure gauge, in particular an ion source (10) according to claim 1;
an extraction device which is provided for forming an ion beam (16a) and/or for directing an ion beam (16a) and/or for extracting ions (16) from the molecules (15) to be ionized which are supplied, which is at least in part a part of the ion source (10) or which is connected to the ion source (10);
a device for accelerating the ions generated in the ion source (10).

11. Method for handling an ion source (10), in particular for generating ions (16) in an ion source (10), in particular an ion source (10) according to claim 1, the ion source (10) being provided in that ions (16) are generated in an ionization process from molecules (15) to be ionized in an ion generation chamber (11) of the ion source (10), characterised in that in that pressure values at/in the ion generation chamber (11) are detected or determined before and/or during and/or after the ionization process via a pressure measuring device (30) assigned to the ion generation chamber (11), the pressure measuring device (30) having a first pressure measuring device (31), which is designed in particular in the form of a gas friction pressure gauge, or which comprises in particular a gas friction pressure gauge.

12. Method according to claim 11, characterised by the following steps:
a) Molecules (15) to be ionized, in particular in a gas stream, are fed into the ion generation chamber (11) of the ion source (10) via a supply (14);
b) In the ionization process, ions (16) are generated from the molecules (15) to be ionized in the ion generation chamber (11).

13. Method according to claim 11, characterised in that the ion source (10) is released or the ionization process is started when the pressure measuring device (30), in particular the first pressure measuring device (31), measures that the pressure value, in particular the vacuum pressure in the ion generation chamber (11), falls below a certain predetermined pressure value.

14. Method according to claim 11, characterised in that by means of the pressure measuring device (30), in particular by means of the first pressure measuring device (31), a mass flow control device (17), which is provided for the supply of the molecules (15) to be ionized, is controlled and/or monitored and/or calibrated.

15. Method according to claim 11, characterised in that the pressure measuring device (30), in particular the first pressure measuring device (31), controls and/or monitors the ion source (10), in particular determines and/or regulates and/or monitors important parameters of the ion source (10), and/or measures the pressure inside the ion generation chamber (11), and/or determines the cleanliness of the components inside the ion generation chamber (11), and/or determines the tightness of the ion source (10).
